(19) United States
(12) Patent Application Publication
(10) Pub. No.: US 2002/0108089 A1
(43) Pub. Date: Aug. 8, 2002

(54) Use of trellis coded modulation to mitigate fading channels in data transmission over air link wireless channels of GPRS/EDGE systems

(75) Inventors: Anthony Reid, Plano, TX (US); Faruk Hadziomerovic, Richardson, TX (US)

Correspondence Address: Andrew J. Dillon, FELSMAN, BRADLEY, VADEN, GUNTER & DILLON, LLP, Suite 350, Lakewood on the Park, 7600B North Capital of Texas Highway, Austin, TX, 78731, US

(73) Assignee: Nortel Networks Limited

(21) Appl. No.: 09/738,755

(22) Filed: Dec. 15, 2000

(51) Int. Cl. H03M 13/03

(52) U.S. Cl. 714/792

(57) ABSTRACT

Disclosed is a system and method for improving efficiency and overall capacity of data transmission within a given bandwidth in a GPRS/EDGE wireless air-link channel. A GPRS data terminal, mobile unit and/or other end-user equipment is equipped with a (specially designed) Trellis coder that replaces the traditional cyclic coder and allows encoding and decoding of data via the Trellis code algorithm. Trellis coder eliminates errors in data transmission, increases capacity in a given bandwidth, and corrects problems with fading channels associated with wireless transmission. The Trellis coder is also utilized for voice transmission and may be fabricated on an integrated circuit for utilization within hand-held devices.

### BACKGROUND OF THE INVENTION

1. Field of the Invention

The present invention relates in general to wireless communications and in particular to a system and method for transmitting data over a wireless channel. Still more particular, the present invention relates to a system and method for providing greater capacity and reduced fading channel effects with transmission of data over a wireless channel of GPRS or EDGE systems.

2. Description of the Related Art

Wireless communication utilizes various defined standards for voice and data communications. Universally accepted standards are General Packet Radio Services (GPRS), a packet-based wireless communication service that provides data rates from 56 up to 114 Kbps and continuous connection to the Internet for mobile phone and computer users, and Enhanced Data GSM Environment (EDGE), a faster version of the Global System for Mobile (GSM) wireless service that is designed to deliver data at rates up to 384 Kbps and enable the delivery of multimedia and other broadband applications to mobile phone and computer users.

The EDGE standard is built on the existing GSM standard, using the same time-division multiple access (TDMS) frame structure and existing cell arrangements. EDGE is designed to provide Universal Mobile Telecommunications Service (UMTS).

GPRS offers higher data rates than traditional standards and allows users to take part in video conferences and interact with multimedia Web sites and similar applications using mobile hand-held devices as well as notebook computers. GPRS is also based on GSM communication and complements existing services such as circuit-switched cellular phone connections and the Short Message Service (SMS). A more in-depth presentation of GSM may be found in Michel Mouly and Marie-Bernadette Pautet: GSM System for Mobile Communications, 1992.

During the initial implementations, wireless telephony was used only for voice communications. Voice recognition is robust to bit error rate, i.e., the human ear is insensitive to most bit error rate found in a typical wireless voice transmission. Thus, these voice-communication systems are typically configured with convolution-based modulation over the air link.

There is a growing desire to be able to efficiently transfer data over the wireless air link as provided with the traditional voice-based wireless transmission systems. Data transmission systems have been designed that utilize the convolution-based modulation. These systems exhibit inherent limitations when attempting to transfer data over the wireless link primarily due to the significant bit error rates due to fading channel phenomena in wireless air link transmission.

Unlike voice communication, data communication does not tolerate errors in transmission. Thus, the GRPS system, which utilizes convolutional coding, though capable of transmitting data at relatively high speeds, is limited by the bit error rate. Spread spectrum in CDMA has been suggested to overcome some of the limitations of convolutional coding, but spread spectrum leads to significant signal interference and does not address the fading channel problem. Also, while the wireless air link bandwidth is limited by industry-allocated spectrum, there is an ever-increasing demand for bandwidth in wireless data communications in GPRS and EDGE.

The present invention recognizes that a method and system that provides both higher capacity and errorless transmission of data over a wireless air link would be desired. The present invention further recognizes that a significant advantage can be achieved by providing better encoding/decoding that substantially eliminates fading channel effects for data being transmitted in GPRS/EDGE systems.

### SUMMARY OF THE INVENTION

Disclosed is a system and method for improving efficiency and overall capacity of data transmission within a given bandwidth in a GPRS/EDGE wireless air-link channel. A GPRS data terminal, mobile unit and/or other end-user equipment is equipped with a (specially designed) Trellis coder that replaces the traditional convolutional coder and allows encoding and decoding of data via the Trellis code algorithm. Trellis coder eliminates errors in data transmission or increases the data rate over a given bandwidth for the same error rate. The Trellis coder is also utilized for voice transmission and may be fabricated on an integrated circuit for utilization within hand-held devices.

The above as well as additional objects, features, and advantages of the present invention will become apparent in the following detailed written description.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 is a block diagram of a GPRS network utilized within a preferred embodiment of the invention;

FIGS. 2A-2C are a series of block diagrams illustrating frame hierarchy for traffic channels according to one embodiment of the invention;

FIG. 3 is a block diagram illustrating a sequence of operations for converting speech/data to radio wave for wireless transmission in accordance with one embodiment of the invention;

FIGS. 4A and 4B illustrate a basic convolutional encoder and the corresponding Trellis diagram, respectively in accordance with one embodiment of the invention;

FIG. 5 is a comparative diagram illustrating an un-coded pulse amplitude modulation model and a Trellis coding model for data transmission with the same average signaling power in accordance with one implementation of the invention;

FIG. 6 is a block diagram illustrating component parts of a Trellis encoder system according to one preferred embodiment of the present invention;

FIGS. 7 and 8 illustrate block diagram representations of an encoder/decoder pair utilized in one preferred embodiment of the invention.

### DETAILED DESCRIPTION OF AN ILLUSTRATIVE EMBODIMENT

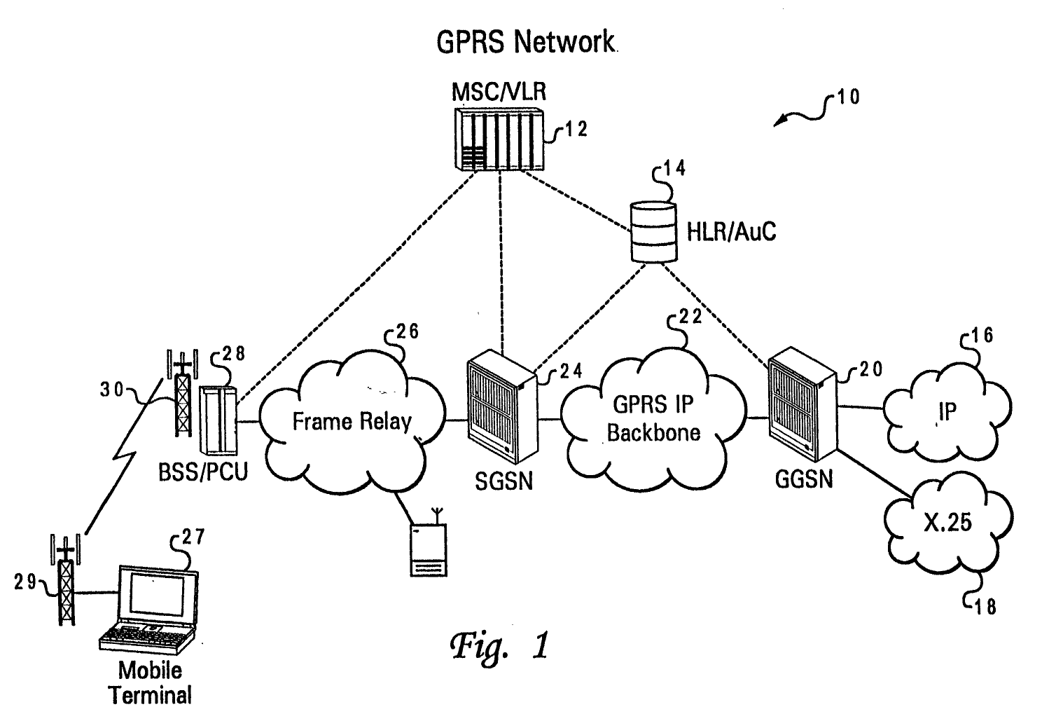

With reference now to the figures and in particular with reference to FIG. 1, there is illustrated a general diagram of the topology of a GPRS network 10 utilized to implement a preferred embodiment of the invention. The GPRS network 10 comprises a mobile switching center (MSC)/visitor location register (VLR) 12, a home location register (HLR) and authentication center (AuC) 14, a gateway GPRS support node (GGSN) 20, a serving GPRS support node (SGSN) 24, and a base station system (BSS)/packet control unit (PCU) 28. BSS has an associated BSS antenna 30, which provides a wireless airlink with mobile terminal 27 via mobile terminal antenna 29. The MSC/VLR 12 provides voice communications for wireless (cellular) terminals. The MSC/VLR 12 is in direct communications with the HLR/AuC 14, the SGSN 24, and the BSS/PCU 28. The HLR/AuC 14 is in direct communications with SGSN 24 and GGSN 20.

The GPRS network 10 is configured to support interfaces to and from packet data networks. FIG. 1 shows that the GGSN 20 is coupled to, and in communications with, outside packet data networks that support the Internet Protocol (IP) 16 or the X.25 protocol 18. In FIG. 1, data packets come in from the outside network (i.e. IP 16 or X.25 networks 18) to the GGSN 20, then to the SGSN 24, and then to the BSS/PCU 28. Thus, two-way communications exist between the BSS/PCU 28 and the SGSN 24, the GGSN 20, and the outside network(s).

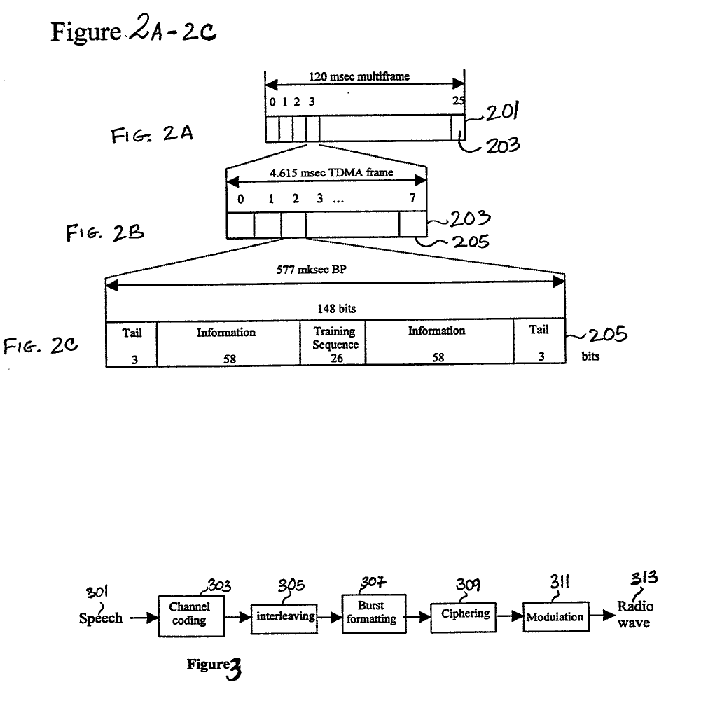

FIGS. 2A-2C, illustrates a 120 msec multi-frame 201, which consists of 26 slots 203 (i.e., time division multiple access (TDMA) frames). Of the 26 slots 203 in the 120 msec multi-frame 201, 25 are used for voice, while 1 is used for signaling. Each slot 203 consists of 8 Burst Periods (BPs) 205 each of 577 mksec duration. One BP 205 within the slot corresponds to one transmission channel (TCH). Because each TCH supports a single conversation in operation, one TCH slot 203 can simultaneous carry 8 conversations.

FIG. 3 illustrates the process (or sequence of operations) required in the conversion of speech or analog signal 301 to radio wave or digital signal (i.e., BP bits) 313, which may then be transmitted via a wireless air link. As represented by the various blocks, several steps are required to complete the process. These steps include channel coding 303, interleaving 305, burst formatting 307, ciphering 309, and modulation 311. The sequence of steps is also utilized when converting data to digital signals 313. A reversed set of steps is utilized to convert received digital signals into their corresponding analog counterparts.

The invention is primarily implemented within the block designated for channel-coding 303. In the preferred embodiment, the function of channel-coding 303 during forward signal transmission is provided by a Trellis channel-encoder block that is specially designed to provide the improvements of the present invention as further described below. Conversely, during signal reception, function of channel-coding 303 is provided by a corresponding specially designed Trellis channel-decoder.

The preferred embodiment of the present invention thus provides a Packet Data Traffic Channel (PDTCH) that utilizes TCM coders to perform channel-coding 313. The invention thus provides a hardware and/or logic system at a data station by which channel coding at the origination station is completed by a TCM encoder and channel decoding at the receiving data station is completed by a TCM decoder. Although described herein as separate components, the invention contemplates utilizing a single encoder/decoder device to perform channel-coding 303.

The preferred embodiment of the invention, as described herein, focuses primarily on Traffic Channel (TCH)/Full Rate (F) (i.e., TCH/F not TCH half rate). The invention provides data accuracy for data traffic, while transmitting data at the highest possible speed and/or capacity by utilizing Trellis Coding over the air link channel PDTCH. Utilization of Trellis Coded Modulation (TCM) significantly expands the data rate within the same available bandwidth. In standard implementation, the data's bit rate is increased at the cost of greater encoder and decoder complexities; however, the additional complexities of both components can be afforded, and the TCM coders are easily incorporated within the wireless data terminals.

In the preferred embodiment, the TCM is placed on top of Quadrature Amplitude Modulation (QAM) which is utilized in the coding sequence. TCM enables robust error immunity for data with significantly increased data rate over the data rates of the methods presently being utilized.

Voice transmissions by mobile phones are not adversely affected by the present coding systems because the bit errors in voice transmission can be tolerated. However, the present invention contemplates also extending the features associated with TCH coding to voice transmission over hand-held mobile units (e.g., mobile phones) to allow for additional capacity for wireless voice communications. Utilization of TCM for voice may significantly increase the number of simultaneous voice conversation within the available bandwidth. Continuing developments in Integrated Circuits (IC) technology allows for the miniaturization of the Trellis encoder and decoder components to allow implementation of IC-level Trellis encoders and decoders to be incorporated within a mobile phone without necessarily increasing the phone or other small, wireless components.

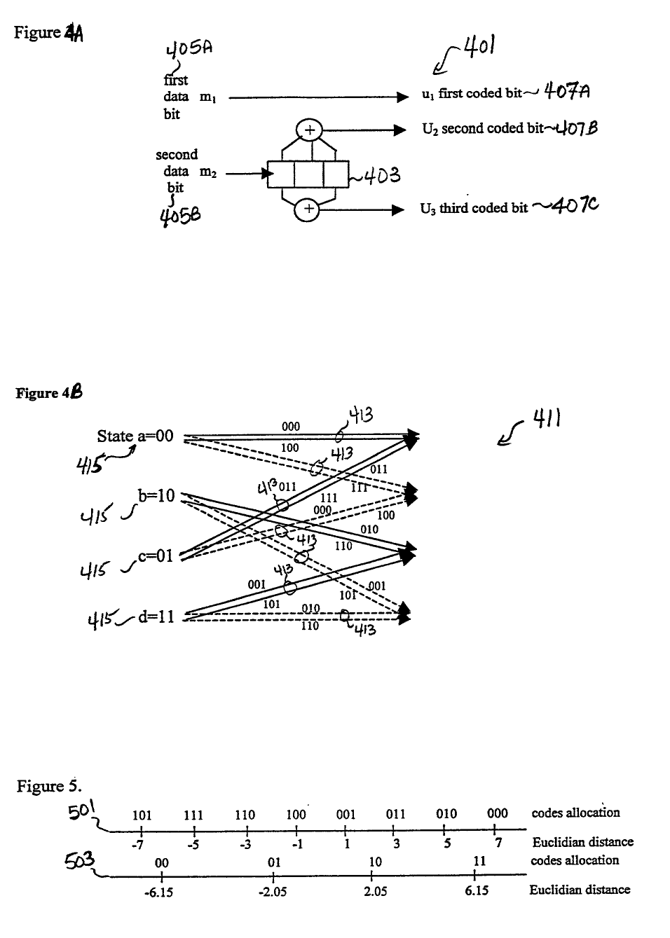

FIGS. 4A and 4B illustrate a simple Trellis Coding example. Trellis Coding is a special case of convolutional coding where coded words are allocated to the signals to obtain the maximum Euclidian distance between “neighboring” words for limited signal power. Obtaining the maximum Euclidian distance increases data rates significantly over the same physical channel and with the same accuracy. In the preferred embodiment, Trellis coding employs Amplitude Phase modulation and thus forms different constellation lattices in the signaling space.

Referring to FIG. 4A, a Rate 2/3 convolutional encoder is illustrated. For the illustrated example, an assumption is made that the convolutional encoder has shift register size K=3. For every pair of input bits the encoder 401 produces 3 output bits 403. The encoder has 4 states and the corresponding Trellis diagram is shown in FIG. 4B.

FIG. 4B illustrates the Trellis diagram 411 for the encoder 401 of FIG. 4A. Trellis coding associates vector signals 413 associated with input states 415 in such a way that Trellis coincidence signals have the maximum Euclidian distance.

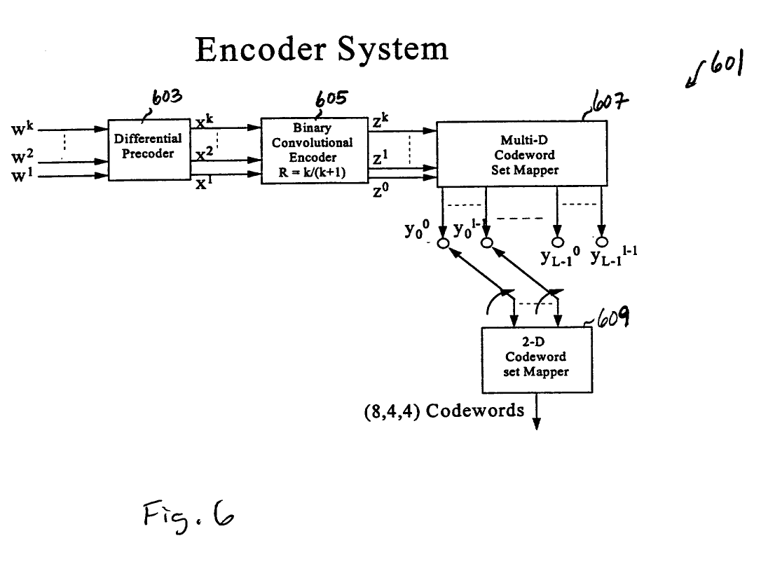

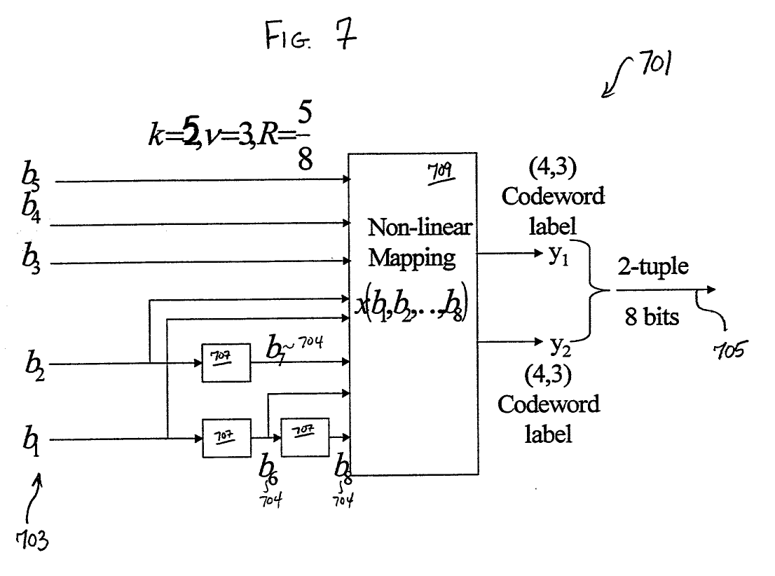

FIG. 5 illustrates results of both the un-coded pulse amplitude modulation (PAM) 503 and Trellis coded modulation 501 and corresponding Euclidian distances for the same average signaling power according to FIG. 4B. From FIG. 5, the average signaling power is calculated as:

Sₐ=Σdᵢ²/M,

where d is the distance from origin or signaling amplitude yielding d² as the signaling power, and M is the number of signals. As calculated, Sₐ=21 in both the un-coded PAM 503 and Trellis coding 501. The immunity to the noise of both coding schemes with the same power may be compared by the minimum Euclidian distance between code words. With the un-coded PAM model 503, the minimum distance is: (6.15−2.05)²=16.8. With Trellis coding 501, the minimum distance is: (7−3)²+(7−5)²+(7−3)²=36.

Therefore, the distance-to-power ratio for the Trellis coding 501 is 36/21=1.71, while that for the un-coded PAM 503 is 16.8/21=0.8. The difference is a factor of 2.14 times worst for the un-coded PAM 503. The Trellis gain in dB is calculated as:

10*log(Trellis/un-coded)=3.3 dB.

As indicated, use of Trellis Coding in GPRS and EDGE increases possible data rate by several order of magnitude. For example, if GPRS maximum data rate with current method is 200 kbps, TCM coding may increase the data rate to over 1 mbps. TCM coding thus enables almost full usage of Shannon's channel capacity, and TCM with QAM enables maximum bit rate for a given bandwidth.

An analysis of design considerations to overcome channel fading in a Trellis coder is provided below. Application of the results of the analysis to actual coder/decoder decisions is provided in Appendix A.

Fading channels present a different problem when designing the Trellis systems described above. To calculate the fading channel effects, the upper bound on Pb average bit error probability is defined as

$${P}_{b} \leq {\sum }_{x ∈ ζ} {\sum }_{\hat{x} ∈ ζ} a ( x , \hat{x} ) p ( x ) P ( x -> \hat{x} ) ,$$

where a(x,\hat{x}) is the number of bit errors that occur when the sequence x is a transmitted sequence and \hat{x}≠x is chosen by the decoder, p(x) is the a-priori probability of transmitting x with ζ the set of coded sequences and finally P(x→\hat{x}) is the pairwise error probability. For the Rayleigh fading channel, the important term in the equation is more specifically defined as

$$P ( x -> \hat{x} ) \leq {( {\prod }_{n ∈ η} \frac{{\overline{E}}_{s}}{4 {N}_{0}} {\vert {x}_{n} - {\hat{x}}_{n} \vert}^{2} )}^{- 1} ,$$

where x=[x₁, x₂, x₃, . . . , xₙ, . . . , x_{N}], \hat{x}=[\hat{x}₁, \hat{x}₂, \hat{x}₃, . . . , \hat{x}ₙ, . . . , \hat{x}_{N}] are vectors with N components and xₙ≠\hat{x}ₙ is the set η. The signal-to-noise ratio is

$$\frac{{\overline{E}}_{s}}{{N}_{0}}$$

A more general form of the equation for Rayleigh or Rician fading channels is

$$P ( x -> \hat{x} ) \leq ( {\prod }_{n ∈ η} \frac{( 1 + K )}{( \frac{{\overline{E}}_{s}}{4 {N}_{0}} ) {\vert {x}_{n} - {\hat{x}}_{n} \vert}^{2}} {e}^{- K} ) , 0 \leq K \leq ∞ ,$$

where K is the Rician coefficient.

The Trellis design rule for a Rayleigh or Rician fading channels is to maximize the number of symbols with non-zero Euclidean distance along the error event path of shortest length. With the above design rules, the following design guidelines are established and utilized by the present invention in designing the associated Trellis coders for the air link wireless channels. First, for any 1-D TCM design the number of parallel branches must be minimized, and second, Multidimensional TCM designs allow multiple symbols per Trellis branch, thus parallel branches can result in diversity gain as long as there are enough differences in the symbols per branch

With multidimensional TCM schemes, there are different methods to increase n in the above equation. One approach, the Trellis-coded multidimensional phase modulation, uses higher dimensional forms of simple constellations (e.g. QPSK, MPSK) to form new constellations (e.g. L X QPSK, L X MPSK). Multiple TCM (MTCM) is another technique that uses higher dimensional forms of simpler constituent constellations. MTCM provides fading channel diversity gain by providing a set partitioning technique that maximizes the number of symbol difference per partition subset. In the preferred embodiment, Trellis-coded multidimensional phase modulation uses a simpler set partitioning method procedure that doesn't necessarily yield the large symbol differences with a sub-set but does yield higher rate codes, thus preserving higher user data rates.

Another approach that increases n is to increase the dimensionality of constellation and use simple constellations (e.g. BPSK) for transmission over the channel. For example, a Gosset lattice is an 8-dimensional lattice that uses constituent Reed-Muller to construct constellation points to transmit over a channel. The Leech lattice is a 24 dimensional lattice that also uses BPSK to transmit code words over the channel. Further diversity gain is achieved by using multidimensional extensions of the same lattices. However, these techniques might not achieve the same bandwidth efficiency gains of higher order modulations but do achieve diversity gain to mitigate fading.

With the above analysis, the present invention thus utilizes a specific approach in designing Trellis coders to reduce fading within transmission channels while providing increased data transmission capacity. The approach utilized by the invention includes the utilization of higher dimensional lattices over simpler modulation schemes or existing modulation schemes, which minimizes the impact to the structure of the modulation for current standards (e.g., GPRS uses GMSK and/or QPSK modulation). The implementation provides burst error correction like Reed-Solomon codes with the 2 dB added benefit of soft-decision decoding via Viterbi decoders. The approach also provides higher rate codes and consequently preserves user data rates.

The approach also includes the utilization of higher dimensional lattices constructed from Reed-Muller codes to exploit the inherent implementation simplicity of these codes, and/or Utilization of multidimensional variants of these higher dimensional lattices (i.e. constellations) to get further diversity gain on the fading channel. A predetermined set partitioning scheme is utilized along with the codeword partitioning scheme to form sub-set partitions. The set partitioning scheme is further described in S. S. Pietrobon, R. H. Deng, A. Lafanechere, G. Ungerboeck and D. J. Costello, Jr., “Trellis-Coded Multidimensional Phase Modulation”, IEEE Transactions on Information Theory, vol. 36, No. 1, January 1990, the content of which is hereby incorporated by reference.

The approach utilized further comprises utilization of exhaustive searching to find the sub-set partitions with the largest symbol difference within a partition. Thus higher diversity gain is achieved along parallel branches as per MTCM. Finally, utilization of fractional dimensional Reed-Muller codes to construct code rates beyond the standard Reed-Muller codes is made and fractional dimensional codes are built to match user data rate requirements.

The design parameters above are utilized to produce several different implementations of Trellis coders as further described in Appendix A, which further describes how the Trellis-coded multidimensional Reed-Muller codes can be applied for the Gosset lattice (E₈).

FIG. 6 is a block diagram illustrating the general structure of an encoder, which may be advantageously utilized within a data terminal of a wireless air link GPRS system in one embodiment of the invention. As illustrated, encoder 601 comprises several functional blocks, including a differential precoder 603, a rate R=k/(k+1) convolutional encoder 605, a multidimensional signal set mapper 607, and a Reed-Muller signal set mapper 609. The differential precoder 603 preserves rotational invariance of signal sets, and the rate R=k/(k+1) convolutional encoder 605 provides redundancy in signal space.

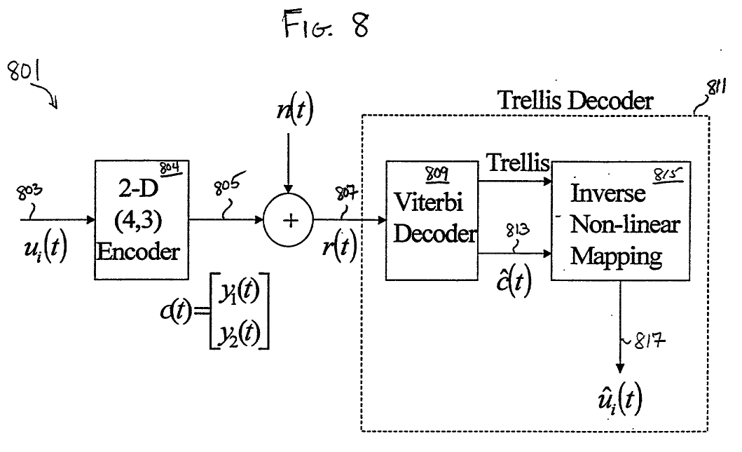

FIGS. 7 and 8 are block diagrams illustrating a Trellis encoder/decoder pair utilized in one preferred embodiment of the invention. The design of the encoding stage is driven by a set of parameters needed to compute bit-error-rate (BER) performance. Encoder 701 has k=5 input bits 703 (i.e., b₁, b₂, . . . , b₅) and 8 output bits 705 (i.e., two 4 bit code words). There are 3 memory elements 707 (i.e. v=3) which generate 3 additional bits 704 (i.e., b₆, b₇, b₈) to the non-linear mapping function. The non-linear mapping function 709 uses the bits b₁, b₂, . . . , b₈ 703 704 to form code words formed by the trellis branches of a multidimensional design. Specific parameters related to the encoder/decoder pair are also provided in Appendix A.

FIG. 8 shows the decoder 801 for the 2-D (4,3) Reed-Muller code. Input message bits 803 with uᵢ(t)=[b₁(t), b₂(t) , . . . , b₅(t)] are encoded by 2-D encoder 804 into code word 2-tuples c(t)=[y₁(t), y₂(t)]^{T} 805 where each y₁(t), y₂(t) is a (4,3) Reed-Muller code word. These code words are modulated and transmitted over an AWGN channel with noise n(t) to Trellis decoder 811. The Viterbi decoder 809 receives channel signal r(t) 807 and forms estimates of channel code words (t) 813 and stores accompanying state progression information in a Trellis. Following, code words (t) 813 are passed through inverse non-linear mapping 815 to produce output 817.

A more detailed analysis of Trellis Coding and types or models of Trellis Coders (encoders/decoders) and their specific implementations, which may advantageously be utilized in the implementation of the present invention may be found in Appendix A, the entire content of which is hereby incorporated by reference.

It is important to note that while the present invention has been described in the context of a fully functional data processing system, those skilled in the art will appreciate that certain elements of the method of the present invention are capable of being distributed in the form of a computer readable medium of instructions in a variety of forms, and that the present invention applies equally, regardless of the particular type of signal bearing media utilized to actually carry out the distribution. Examples of computer readable media include: nonvolatile, hard-coded type media such as Read Only Memories (ROMs) or Erasable, Electrically Programmable Read Only Memories (EEPROMs), recordable type media such as floppy disks, hard disk drives and CD-ROMs, and transmission type media such as digital and analog communication links.

While the invention has been particularly shown and described with reference to a preferred embodiment, it will be understood by those skilled in the art that various changes in form and detail may be made therein without departing from the spirit and scope of the invention.

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

What is claimed is:

1. A system for transmitting data over a wireless channel said system comprising:
a Trellis coder that specifically encodes said data to substantially eliminate fading on a transmission channel and increase capacity on an allocated bandwidth; and
a wireless transmitter that transmits said encoded data over said wireless channel.

2. The system of claim 1, further comprising a quadrature amplitude modulator that modulates said encoded data to increase a number of simultaneous transmissions within said allocated bandwidth.

3. The system of claim 1, further comprising a digital converter that converts said data into radio waves to enable wireless transmission.

4. The system of claim 3, wherein said Trellis coder includes a Trellis decoder and decodes encoded data received from a next system across said wireless channel.

5. The system of claim 3, wherein said Trellis coder is a Trellis encoder, said system further comprising a Trellis decoder that decodes encoded data received from a next system across said wireless channel.

6. The system of claim 3, wherein said Trellis coder is located on an integrated circuit within a wireless component.

7. The system of claim 6, wherein said wireless component is a voice communication device and said Trellis coder further encodes and decodes voice communication.

8. The system of claim 1, wherein said Trellis coder provides a maximum Euclidean distance between words of said data during encoding to substantially reduce signal power required for said wireless transmission.

9. A GPRS/EDGE network for wireless transmission comprising:
a data transmission station and a data receiving station;
wherein said data transmission station including a wireless transmitter and said data receiving station including a wireless receiver;
wherein said data transmission station comprises a Trellis encoder that specifically encodes data being transmitted to substantially eliminate fading on a transmission channel between said data transmission and data receiving stations, reduces signal power required for transmission of said data, and increase capacity on an allocated bandwidth.

10. The GPRS/EDGE network of claim 9, wherein said data receiving station comprises a Trellis decoder that decodes said encoded data.

11. The GPRS/EDGE network of claim 10, wherein said data transmission station comprises a quadrature amplitude modulator that modulates said encoded data to increase a number of simultaneous transmissions within said allocated bandwidth.

12. The GPRS/EDGE network of claim 9, wherein said data transmission station is a mobile station.

13. The GPRS/EDGE network of claim 12, wherein said Trellis encoder is located on an integrated circuit within said mobile station.

14. The GPRS/EDGE network of claim 13, wherein said data is voice data.

15. A method for implementing Trellis coding within a wireless network, said method comprising:
receiving data for transmission over a wireless link of said wireless network;
evaluating a maximum Euclidian distance between code words of said data to reduce signal power requirements;
minimizing fading channel considerations among said code words;
encoding said data utilizing results of said evaluating and minimizing steps; and
transmitting said encoded data over said wireless link.

16. The method of claim 15, further comprising the step of modulating said encoded data utilizing quadrature amplitude modulation that increases a number of simultaneous transmissions within an available bandwidth.

17. The method of claim 15, further comprising the step of decoding said Trellis encoded data received via said wireless air link.

18. A computer program product comprising:
a computer readable medium; and
program instructions on said computer readable medium for:
receiving data for transmission over a wireless link of said wireless network;
evaluating a maximum Euclidian distance between code words of said data to reduce signal power requirements;
minimizing fading channel considerations among said code words;
encoding said data utilizing results of said evaluating and minimizing steps; and
transmitting said encoded data over said wireless link.

19. The computer program product of claim 18, further comprising program instructions for modulating said encoded data utilizing quadrature amplitude modulation that increases a number of simultaneous transmissions within an available bandwidth.

20. A method of data transmission over a wireless air link in GPRS/EDGE, said method comprising the steps of:
encoding said data at a transmission origination point for transmission over a wireless air link utilizing a Trellis encoder designed to mitigate fading within transmission channels; and
decoding radio wave signals received from said wireless air link via a Trellis decoder wherein channel fading due to said wireless air link is substantially reduced.

21. The method of claim 20, further comprising the step of modulating said encoded data utilizing Quadrature Amplitude Modulation (QAM) to increase capacity and data rates within an available bandwidth.

22. The method of claim 21, wherein said encoding step includes the step of maximizing an Euclidean distance between neighboring words of said data to reduce signal power required for transmission of said data.

23. The method of claim 22, wherein said Trellis coding utilizes Amplitude Phase Modulation to form constellation lattices in a signaling space.
